(19) United States
(12) Patent Application Publication
(10) Pub. No.: US 2024/0049430 A1
(43) Pub. Date: Feb. 8, 2024

(54) COOLING DEVICE

(71) Applicant: Nidec Corporation, Kyoto (JP)

(72) Inventors: Tsung-Ting HSIEH, Taipei (TW); Kwun-Yao HO, Taipei (TW)

(21) Appl. No.: 18/265,695

(22) PCT Filed: Jun. 11, 2021
(86) PCT No.: PCT/JP2021/022339

§ 371 Date: Jun. 7, 2023

(30) Foreign Application Priority Data
Dec. 16, 2020 (JP) 2020-208376

(51) Int. Cl. H05K 7/20

(52) U.S. Cl. CPC H05K 7/20336; H05K 7/20327

(57) ABSTRACT

A cooling device includes a first surface portion thermally connected to one or more heating elements, a second surface portion opposed to the first surface portion, a flow path between the first and second surface portions and through which the cooling fluid flows, and a side wall connecting the first and second surface portions and extending along the direction in which the cooling fluid flows. A height of the side wall is reduced from the second surface portion side toward the first surface portion side at an outlet of the flow path. At least a portion of the second surface portion is missing in a portion of the side wall of which the height is reduced. A portion where the side wall is in contact with the first surface portion is superimposed on at least an entirety of the heating element closest to the outlet of the flow path.

### CROSS-REFERENCE TO RELATED APPLICATIONS

This is a U.S. national stage of application No. PCT/JP2021/022339, filed on Jun. 11, 2021, with priority under 35 U.S.C. § 119(a) and 35 U.S.C. § 365(b) being claimed from Japanese Patent Application No. 2020-208376, filed on Dec. 16, 2020, the entire disclosures of which are hereby incorporated herein by reference.

### FIELD OF THE INVENTION

The present disclosure relates to a cooling device that cools a heating element such as a semiconductor element.

### BACKGROUND

A cooling device that cools a semiconductor element such as an insulated gate bipolar transistor (IGBT) is known. In the cooling device, a plurality of vertical fins are provided on a horizontal plate member, and an inter-fin passage extending in a horizontal direction (a direction in which a coolant flows) is formed between the fins. Then, a substantially rectangular parallelepiped flow path is formed as an aggregate of a plurality of the inter-fin passages, and the coolant flows through the flow path to cool the semiconductor element that is a heating element. A surface area of the rectangular parallelepiped flow path (the size of the surface in contact with the heating element) and the size of the fin greatly affect a cooling capacity of the cooling device.

In the conventional cooling device, the flow path extends in the horizontal direction, and height of each fin, which is a side wall of the flow path, is unchanged from an inlet to an outlet of the flow path, so that the coolant easily flows in and out the flow path in the horizontal direction. However, when the coolant flows in and out the flow path in a vertical direction, it is necessary to remove the fins at the inlet and the outlet of the flow path to secure a space (transition section) for gradually changing the direction of the coolant flowing in the vertical direction and flowing the coolant in the horizontal direction. Since such a space eliminates a part (inlet/outlet) of the flow path, the surface area of the flow path decreases and the cooling capacity of the cooling device descends.

### SUMMARY

A cooling device according to a preferred embodiment of the present disclosure cools, with a cooling fluid, one or more heating elements provided along a direction in which the cooling fluid flows. The cooling device includes a first surface portion thermally connected to the one or more heating elements, a second surface portion opposed to the first surface portion, a flow path located between the first surface portion and the second surface portion and through which the cooling fluid flows, and a side wall connecting the first surface portion and the second surface portion and extending along a direction in which the cooling fluid flows. A height of the side wall is reduced from the second surface portion side toward the first surface portion side at an outlet of the flow path. At least a portion of the second surface portion is missing in a portion of the side wall of which the height is reduced. A portion where the side wall is in contact with the first surface portion is superimposed on at least an entirety of the heating element closest to the outlet of the flow path.

In a case where the heating elements are provided on a lower surface of the first surface portion, a structure in which the height of the side wall is reduced toward the first surface portion side at the outlet of the flow path and at least a portion of the second surface portion is missing in the portion of the side wall of which the height is reduced is a structure in which an upper portion of the flow path is cut off. Since the upper portion of the flow path is cut off, when the cooling fluid flows out the flow path, the cooling fluid easily flows out in a vertical direction from a flow path bottom portion. In addition, since a lower portion of the flow path is not cut off, at the flow path outlet, the bottom portion of the flow path makes it possible to cover an entirety of a most downstream heating element in plan view. By covering the entirety of the most downstream heating element at the flow path outlet, a cooling capacity of the most downstream heating element is prevented from being decreased.

The height of the side wall may be reduced from the second surface portion side toward the first surface portion side also at an inlet of the flow path.

The cooling device may further include a first protrusion that is provided on the side wall to direct a flow of the cooling fluid toward the first surface portion.

The cooling device may further include a second protrusion that is provided on the side wall in a lower stream with respect to the first protrusion to direct the flow of the cooling fluid toward a low flow velocity area generated by the first protrusion.

Each of positions where the first protrusion and the second protrusion are provided may correspond to a position of each of the one or more heating elements.

The first protrusion may be inclined at a first predetermined angle with respect to the direction in which the cooling fluid flows in the flow path, and the second protrusion may be inclined at an angle different from the first predetermined angle with respect to a longitudinal direction of the flow path. Alternatively, each of the first protrusion and the second protrusion may be inclined at substantially 30 degrees with respect to the longitudinal direction of the flow path.

A height of the portion of the side wall of which the height is reduced may be about ½ or less of the height of a portion of which the height is not reduced.

The height of the portion of the side wall of which the height is reduced may not be constant.

The first protrusion and the second protrusion may be in contact with a side wall opposed to the side wall.

The first protrusion and the second protrusion may be formed by punching.

The one or more heating elements may be provided on the first surface portion via a plate-shaped portion, and the plate-shaped portion may be a copper plate. The plate-shaped portion may be replaced with a vapor chamber including a copper housing.

The one or more heating elements may be provided on the first surface portion via a heat pipe.

At least one of the one or more heating elements may be an insulated gate bipolar transistor.

The first surface portion, the side wall, and the second surface portion may be defined by one metal plate having a U-shape. The flow path may be defined by connecting a plurality of the metal plates each of having the U-shape in a direction parallel to the first surface portion and perpendicular to the direction in which the cooling fluid flows.

The metal plate having the U-shape may be a fin portion. Further, the flow path may be defined by a plurality of the fin portions. The metal plate may be a copper plate.

The side wall may be a plurality of heat dissipation fins each of provided vertically from the first surface portion toward the second surface portion.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1A is an appearance perspective view of a cooling system including a cooling device according to a first example embodiment of the present disclosure.

FIG. 1B is a perspective view of the cooling system of FIG. 1A.

FIG. 1C is a perspective view of the cooling device and semiconductor elements cooled by the cooling device.

FIG. 2A is a perspective view of the cooling device.

FIG. 2B is a diagram illustrating one of a plurality of fins constituting a flow path.

FIG. 2C is a side view of the fin illustrated in FIG. 2B.

FIG. 3A is a bottom view illustrating a state in which the three semiconductor elements are attached to the flow path (cooling device) via a board member, and FIG. 3B is a side view of FIG. 3A.

FIG. 4 is a cross sectional view illustrating a flow of a cooling fluid in the vicinity of an outlet of the flow path.

FIG. 5 is a cross sectional view illustrating the flow of the cooling fluid in the vicinity of the flow path outlet according to a first comparative example.

FIG. 6 is a cross sectional view illustrating the flow of the cooling fluid in the vicinity of the flow path outlet according to a second comparative example.

FIG. 7 is a bottom view of the second comparative example.

FIG. 8 is a diagram explaining protrusions provided on a fin according to an example embodiment of the present disclosure.

FIG. 9 is a diagram explaining a third comparative example.

FIG. 10 is a perspective view of a cooling system including a cooling device according to a second example embodiment of the present disclosure.

FIG. 11 is a schematic cross sectional view of the cooling device according to the second example embodiment.

FIG. 12 is an enlarged cross sectional view illustrating a fourth comparative example.

### DETAILED DESCRIPTION

Example embodiments of the present disclosure will be described in detail with reference to the accompanying drawings hereinafter. Each example embodiment described below is an example of the present disclosure, and should be appropriately modified or changed according to a configuration of an apparatus or system to which the present disclosure is applied and various conditions, and the present disclosure is not limited to the following example embodiments.

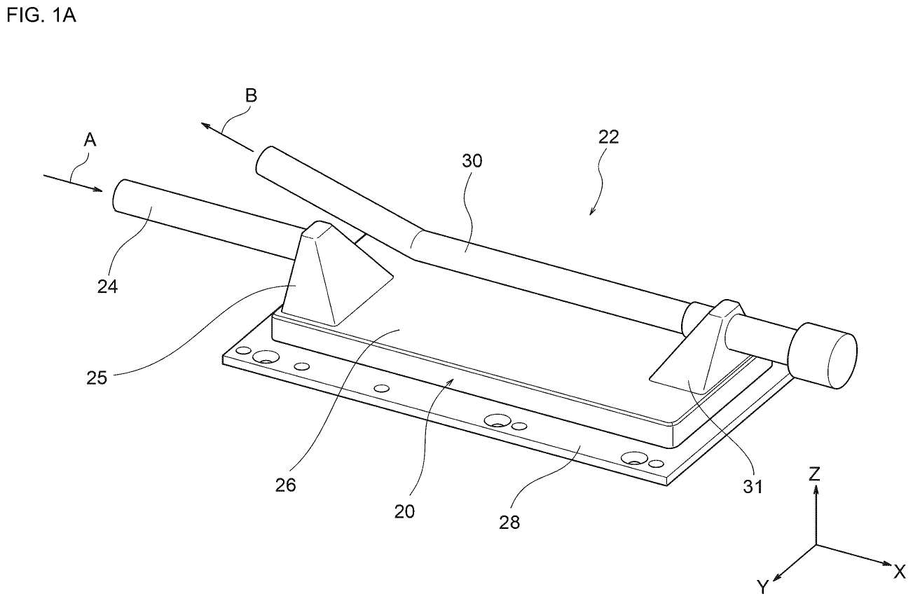

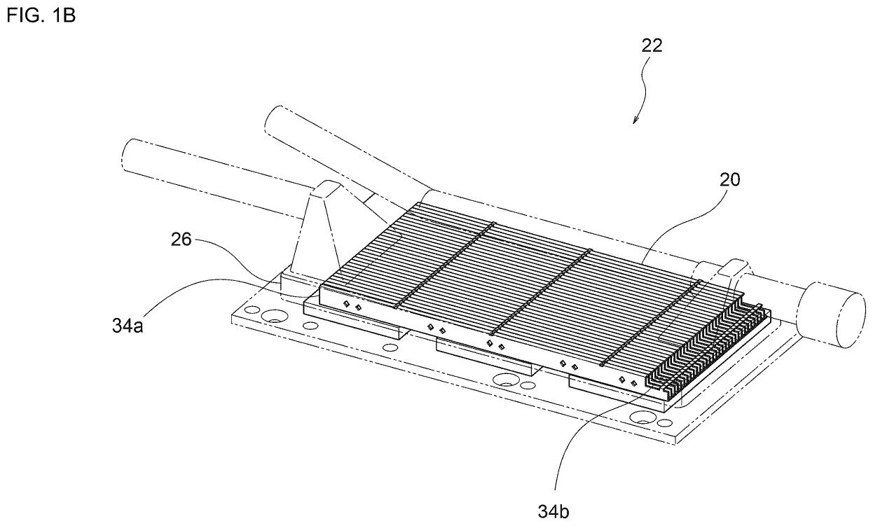

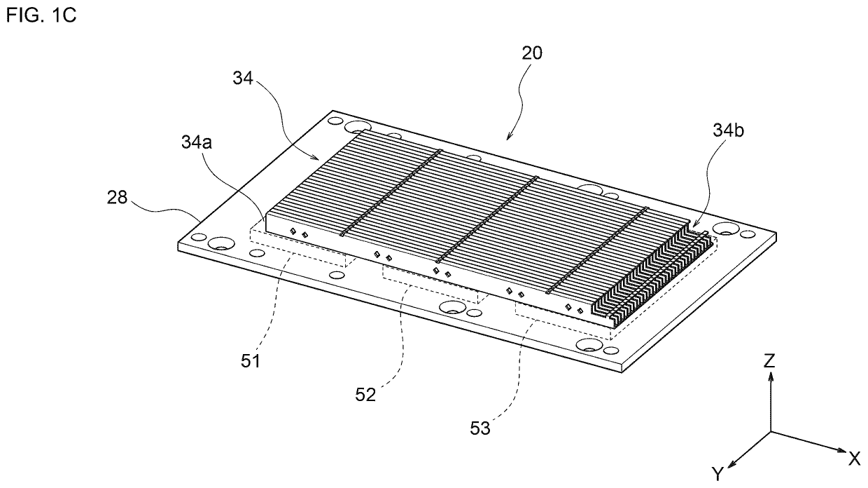

FIG. 1A is an appearance view of a cooling system 22 including a cooling device 20 according to a first example embodiment of the present disclosure. FIG. 1B is a perspective view of the cooling system 22 of FIG. 1A. FIG. 1C is a perspective view of the cooling device 20, a board member 28 on which the cooling device 20 is placed, and three semiconductor elements 51, 52, and 53 located under the board member 28 and cooled by the cooling device 20. An introduction pipe 24 for a cooling fluid described later, a first connection portion 25, a cover member 26, a second connection portion 31, and an outflow pipe 30 are not illustrated in FIG. 1C. In the present example embodiment, the semiconductor elements 51, 52, and 53 are assumed to be insulated gate bipolar transistors (IGBT).

The cooling system 22 includes the introduction pipe (inlet-side pipe) 24 that introduces the cooling fluid (arrow A) into the cooling device 20, the cover member 26 that covers the cooling device 20, the board member 28 on which the cover member 26 is placed, and the outflow pipe (outlet-side pipe) 30 through which the cooling fluid (arrow B) flowing out of the cooling device 20 flows. The cooling device 20 is located on the board member 28 and inside the cover member 26. The cooling fluid is, for example, water or oil. The board member 28 is, for example, a copper plate. Although the board member 28 (copper plate) is provided between the semiconductor elements 51 to 53 and the cooling device 20, a high thermal conductivity of copper allows a cooling capacity of the cooling device 20 to be maintained.

In the present specification, a longitudinal direction of the board member 28 shown in FIG. 1A is referred to as an X direction, a height direction of the board member 28 is referred to as a Z direction, and a direction perpendicular to the X direction and the Z direction is referred to as a Y direction. A plane defined by the X direction and the Y direction is referred to as a horizontal plane in the present example embodiment. In addition, the Z direction may be referred to as a vertical direction. A +Z direction is referred to as an upper direction, and a −Z direction is referred to as a lower direction.

The first connection portion 25 that connects the introduction pipe 24 to one end (left end in FIG. 1A) of the cover member 26 is provided at a downstream end of the introduction pipe 24. A downstream end of the first connection portion 25 is connected to a flow path inlet 34a of the cooling device 20. The second connection portion 31 that connects the outflow pipe 30 to the other end (right end in FIG. 1A) of the cover member 26 is provided at an upstream end of the outflow pipe 30. An upstream end of the second connection portion 31 is connected to a flow path outlet 34b of the cooling device 20.

The cooling fluid flowing in through the introduction pipe 24 as indicated by an arrow A flows in a substantially horizontal direction up to the first connection portion 25. A traveling direction of the cooling fluid that has reached the first connection portion 25 is changed from the horizontal direction to a vertical direction by the first connection portion 25 and flows downward. When the cooling fluid flows in the cover member 26 from the first connection portion 25, the cooling fluid flows through a flow path 34 of the cooling device 20 in the horizontal direction.

That is, the cooling fluid flows in the X direction in parallel with the board member 28. The traveling direction of the cooling fluid that has reached the flow path outlet 34b of the cooling device 20 is changed from the horizontal direction to the vertical direction by the second connection portion 31 and flows upward. Then, the cooling fluid flows from the second connection portion 31 to the outflow pipe 30 and is discharged from the cooling system 22 as indicated by an arrow B.

The board member 28 is a rectangular plate-shaped portion as illustrated in FIG. 1C. A longitudinal direction of the board member 28 coincides with the X direction. Since the three semiconductor elements 51, 52, and 53 are provided on a lower surface of the board member 28, they are drawn by broken lines in FIG. 1C. The cooling device 20 has a substantially rectangular parallelepiped shape, and the flow path 34 through which the cooling fluid flows in the X direction is formed inside the cooling device 20. In the present example embodiment, a height of the flow path 34 on the outlet 34b side (right side in the figure) is small.

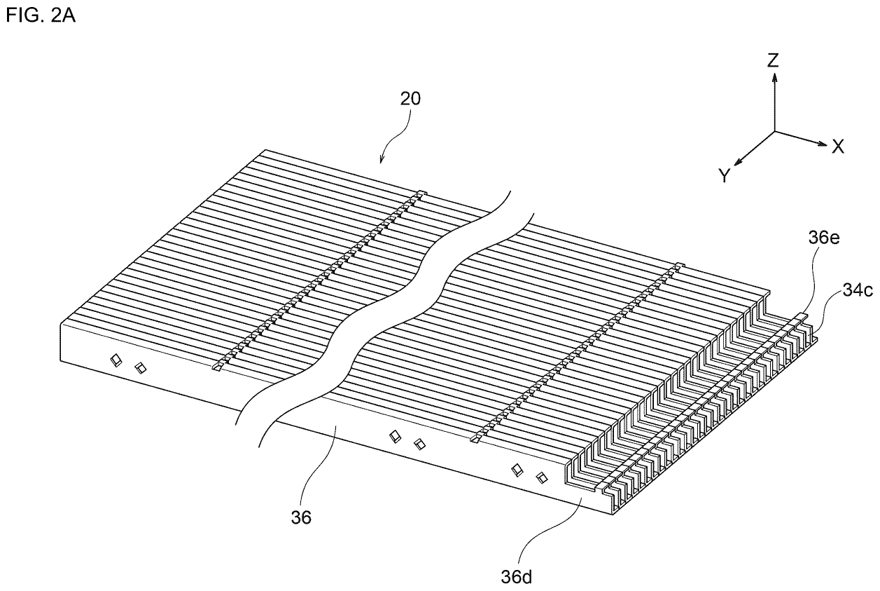

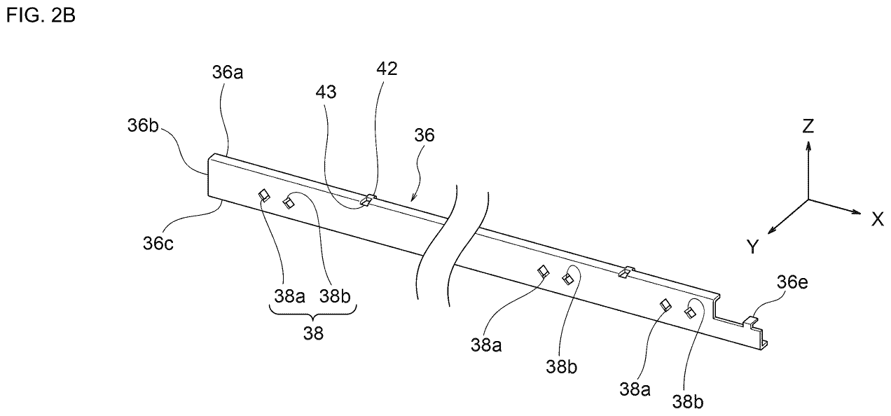

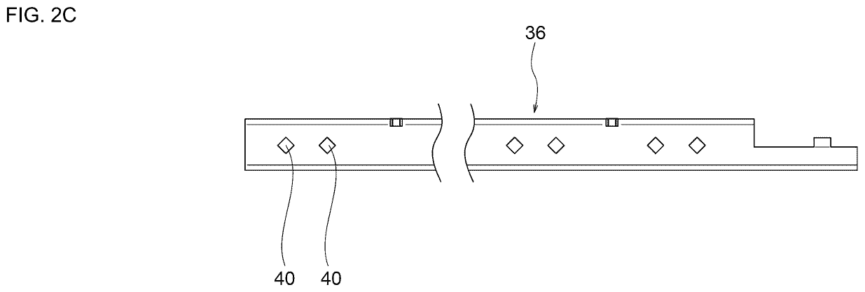

FIG. 2A is a perspective view of the cooling device 20, and FIG. 2B is a view illustrating one of a plurality of fins 36 constituting the flow path 34. FIGS. 2A and 2B are perspective views as viewed from a −Y direction. FIG. 2C is a side view of the fin 36 as viewed from the Y direction, and illustrates a back side of the fin 36 in FIG. 2B.

As seen from FIG. 2B, the fin 36 has a U-shaped cross section when viewed in the X direction. A portion corresponding to an upper side of the U-shape is referred to as an upper surface portion 36a of the fin 36, a portion corresponding to a bottom side is referred to as a lower surface portion 36c of the fin 36, and a portion corresponding to a vertical side connecting the upper surface portion and the lower surface portion is referred to as a side surface portion 36b of the fin 36. Each fin 36 is formed of a U-shaped metal plate. The metal plate (fin 36) is, for example, a copper plate. Copper has a high thermal conductivity, and is suitable as a material for forming the cooling device 20.

The lower surface portion 36c of the fin 36 may be referred to as a first surface portion, the upper surface portion 36a may be referred to as a second surface portion, and the side surface portion 36b may be referred to as a side wall. The second surface portion (upper surface portion 36a) is a surface portion opposed to the first surface portion (lower surface portion 36c). The flow path 34 through which the cooling fluid flows is formed between the first surface portion (lower surface portion 36c) and the second surface portion (upper surface portion 36a). The side wall 36b is a side wall that connects the first surface portion and the second surface portion and extends along a direction in which the cooling fluid flows.

As seen from FIG. 2B, the side surface portion 36b of each fin 36 is provided with a plurality of protrusions 38a, 38b. In the present example embodiment, two protrusions 38a, 38b constitute a pair of protrusions 38, and a plurality of the pairs of protrusions 38 are provided on the side surface portion 36b of the fin 36. The plurality of pairs of protrusions 38 are arranged in the X direction at predetermined intervals. In the following description, the protrusion 38a may be referred to as a first protrusion, and the protrusion 38b may be referred to as a second protrusion. In FIG. 2B, the first protrusions 38a and the second protrusions 38b protrude from a paper surface to this side (protrude in the Y direction). The first protrusions 38a and the second protrusions 38b are formed by punching. In FIG. 2C, although the first protrusions 38a and the second protrusions 38b are not visible, rhombic holes 40 formed by the punching are shown. Details of the first protrusion 38a and the second protrusion 38b will be described later.

As seen from FIG. 2B, the upper surface portion 36a of each fin 36 is provided with a plurality of detent portions 42 and engagement holes 43. The cooling device 20 (flow path 34) is configured by connecting the plurality of U-shaped fins 36 (FIG. 2B) in the −Y direction.

That is, the cooling device 20 is formed by connecting the plurality of fins 36 in a direction parallel to the upper surface portion 36a and perpendicular to the X direction (direction in which the cooling fluid flows). When the fins 36 are connected to each other in the −Y direction, the detent portion 42 of one fin 36 is engaged with the engagement hole 43 of the adjacent fin 36. An inter-fin passage 34c extending in the X direction is formed between the fins 36 adjacent to each other, and a plurality of the inter-fin passages 34c constitute the flow path 34. The first protrusion 38a and the second protrusion 38b protrude from the side wall 36b of one fin 36 and come in contact with the side wall 36b of the other fin 36 between the adjacent fins 36.

That is, a width (dimension in the Y direction) of the inter-fin passage 34c is equal to the protrusion amount of each of the first protrusion 38a and the second protrusion 38b.

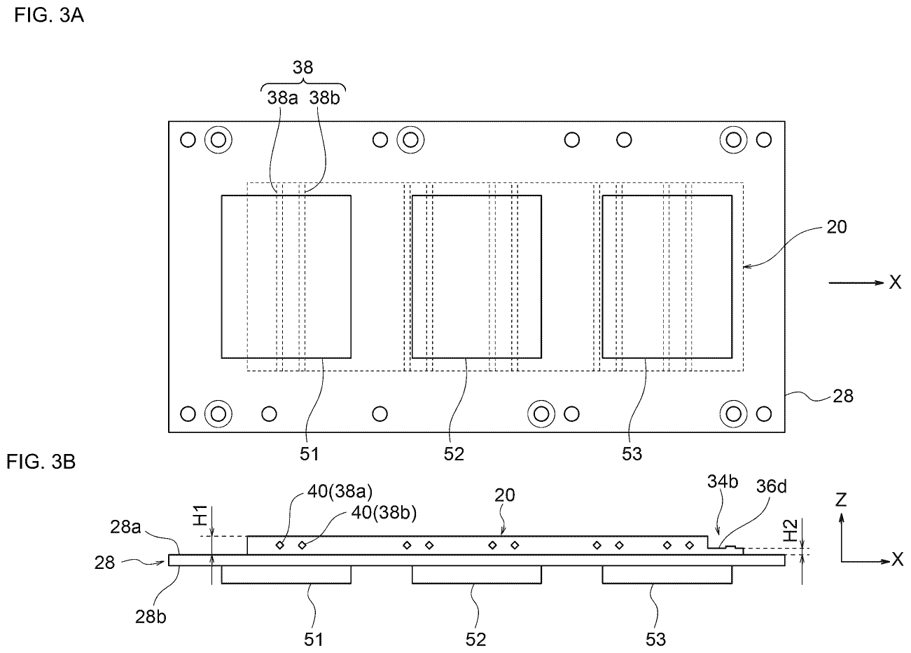

FIG. 3A is a bottom view illustrating a state in which the three semiconductor elements 51, 52, and 53 are attached (thermally connected) to the cooling device 20 via the board member 28, and FIG. 3B is a side view. As seen from FIG. 3B, the semiconductor elements 51, 52, and 53 are provided on a lower surface 28b of the board member 28 at predetermined intervals along the direction (X direction) in which the cooling fluid flows. The cooling device 20 is provided on an upper surface 28a of the board member 28. Assuming that the lower surface portion 36c of each fin 36 is referred to as the first surface portion, it is to be said that the first surface portion 36c of each fin 36 is a surface portion thermally connected to one or more heating elements (semiconductor elements 51 to 53) via the board member 28.

As illustrated in FIG. 3A, in the present example embodiment, among the three semiconductor elements 51 to 53, the semiconductor elements 52, 53 are entirely located under the cooling device 20.

That is, an entire upper surface of the semiconductor element 52 is in contact with the cooling device 20 (via the board member 28), and an entire upper surface of the semiconductor element 53 is also in contact with the cooling device 20 (via the board member 28). With the above configuration, a portion where the side wall portion 36b of each fin 36 is in contact with the lower surface portion 36c is superimposed on at least the entire semiconductor element 53 closest to the outlet 34b of the flow path 34. When the cooling fluid flows in the flow path 34 in the X direction, heat of the semiconductor elements 51, 52, and 53 as the heating elements is transferred to the cooling fluid, so that a temperature of the cooling fluid rises as going from an upper stream to a lower stream of the flow path 34. Thus, the entire semiconductor element 53 is positioned under the cooling device 20 so that the semiconductor element 53 as the most downstream heating element also makes it possible to be sufficiently cooled by the cooling device 20.

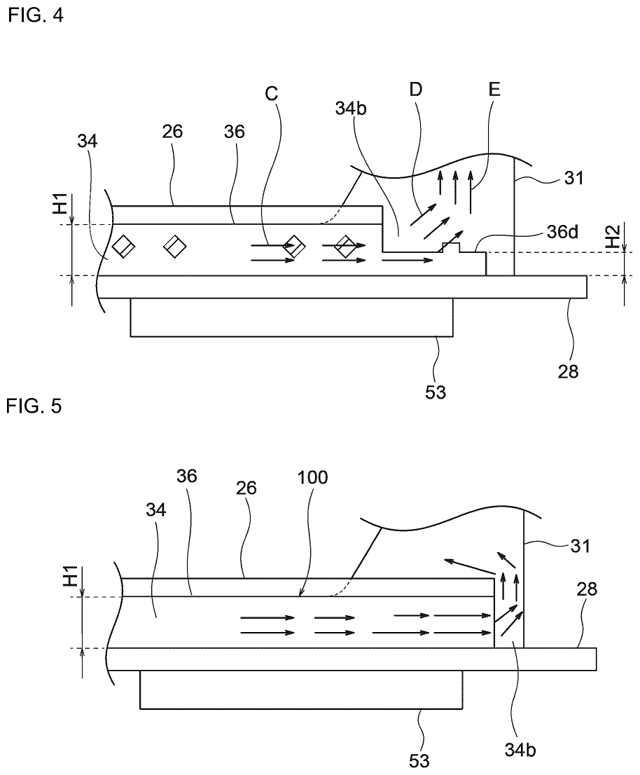

In the present example embodiment, a height of the side wall 36b of each fin 36 is reduced from the upper surface portion 36a toward the lower surface portion 36c side at the outlet 34b of the flow path 34. More specifically, a height H1 of each fin 36 is half or less (height H2) at the outlet 34b of the flow path 34. That is, a height H2 of a portion of the side wall 36b of which the height is reduced is ½ or less of the height H1 of the portion of which the height is not reduced. The reason why the height of the fin 36 is reduced from H1 to H2 will be described with reference to FIG. 4. The portion in which the height of each fin 36 is reduced is referred to as a low back portion 36d. In the present example embodiment, it is assumed that the height H2 of the low back portion 36d is constant. In the low back portion 36d, the upper surface portion 36a of each fin 36 is removed except for a part (36e).

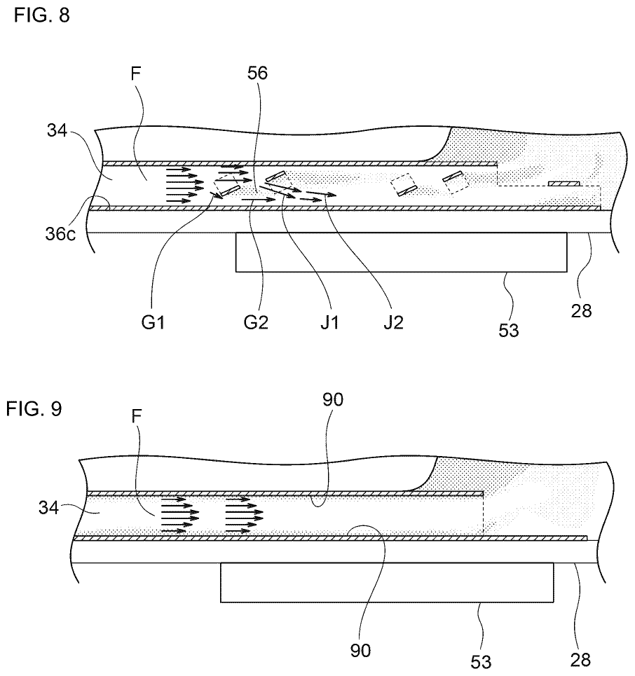

FIG. 4 is a cross sectional view of the vicinity of the outlet 34b of the flow path 34. In FIG. 4, the second connection portion 31 and the cover member 26 are also illustrated. As described above, in the present example embodiment, the height of each fin 36 is half or less at the outlet 34b of the flow path 34. In the low back portion 36d, most of the upper surface portion 36a of the fin 36 is removed. Thus, the cooling fluid (arrows C) flowing horizontally in the flow path 34 in the X direction smoothly changes the direction from the low back portion 36d toward the second connection portion 31 as indicated by arrows D at the outlet 34b of the flow path 34. When the cooling fluid flows in the second connection portion 31, the cooling fluid flows in the Z direction as indicated by arrows E. In FIG. 4, the change in the flow of the cooling fluid by the protrusions 38a, 38b is ignored in order to simplify the description. The change in the flow of the cooling fluid by the protrusions 38a, 38b will be described later with reference to FIG. 8.

In the structure of FIG. 4, the height of the side wall 36b is reduced from the upper surface portion 36a side to the lower surface portion 36c side at the outlet 34b of the flow path 34. It is to be said that the above structure is a structure in which the upper portion of the flow path 34 (upper portion of the cooling device 20) is cut off. Since the upper portion of the flow path 34 is cut off, when the cooling fluid flows out from the flow path 34, the cooling fluid easily flows out in the vertical direction from a flow path bottom portion (lower surface portion 36c). That is, in the structure of FIG. 4, the low back portion 36d forms a transition section for gradually changing the traveling direction of the cooling fluid from the horizontal direction to the vertical direction.

In addition, since a lower portion (lower surface portion 36c) of the flow path 34 is not cut off, a bottom portion of the cooling device 20 makes it possible to cover the whole of the semiconductor element 53 in plan view at the flow path outlet 34b. Since the temperature of the cooling fluid increases as the cooling fluid flows downstream, a decrease in a cooling capacity to the most downstream heating element (semiconductor element 53) at the flow path outlet becomes a problem. In the present example embodiment, the cooling device 20 covers the entire semiconductor element 53 so as not to decrease the cooling capacity to the semiconductor element 53.

Effects of the present example embodiment achieved by the above-described configuration will be described with reference to FIGS. 5, 6, and 7.

FIG. 5 is a cross sectional view of the vicinity of the flow path outlet 34b in a cooling device 100 of a first comparative example. In the first comparative example, the height of each fin 36 remains H1, and the fin 36 does not have the low back portion. In the first comparative example, a length of each fin 36 in the X direction is the same as that in FIG. 4. In the first comparative example, since the low back portion 36d is not formed in each fin 36, there is no transition section for gradually changing the direction of the cooling fluid from the horizontal direction to the vertical direction. Thus, a flow of the cooling fluid is throttled at the flow path outlet 34b, and the cooling fluid makes it impossible to smoothly flow from the flow path 34 to the second connection portion 31.

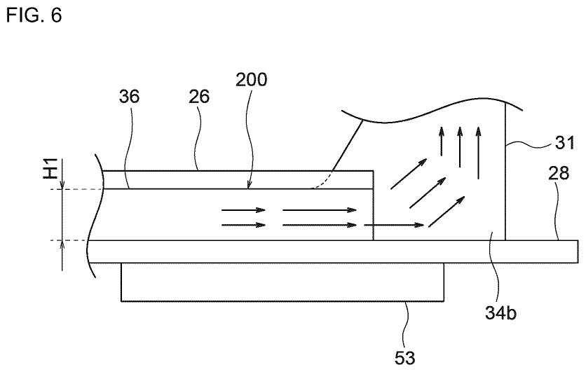

FIG. 6 is a cross sectional view of the vicinity of the flow path outlet 34b in a cooling device 200 of a second comparative example. In the second comparative example, the length of each fin 36 in the X direction is shortened in order to provide the transition section for gradually changing the direction of the cooling fluid from the horizontal direction to the vertical direction. The height of each fin 36 remains H1, and the fin 36 does not have the low back portion, which are the same as the first comparative example.

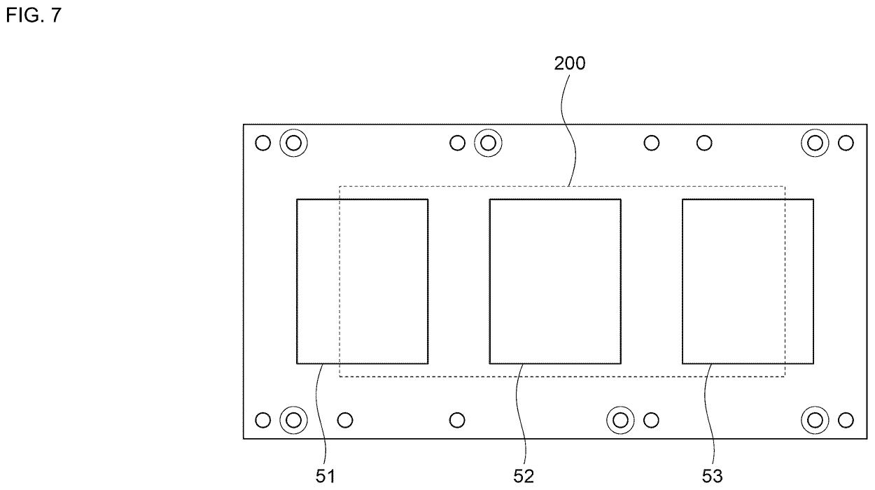

In the second comparative example, the cooling fluid makes it possible to gradually change its own direction from the horizontal direction to the vertical direction. However, since the transition section for gradually changing the traveling direction of the cooling fluid is provided, a bottom surface of the cooling device 200 is cut off, and the cooling device 200 makes it impossible to cover the whole of the semiconductor element 53. As a result, the cooling capacity to the semiconductor element 53 decreases. FIG. 7 is a bottom view of the second comparative example. As illustrated in FIG. 7, the cooling device 200 does not cover the whole of the semiconductor element 53.

As compared with the first comparative example and the second comparative example, the cooling device 20 (FIG. 4) of the present example embodiment allows the cooling fluid in the flow path outlet 34b to smoothly flow without decreasing the cooling capacity to the semiconductor element 53.

Then, the protrusions 38 of the cooling device 20 of the present example embodiment will be described with reference to FIG. 8. In describing action of the protrusions 38, the flow of the cooling fluid in a configuration in which the protrusions 38 are not provided (third comparative example) will be described with reference to FIG. 9.

As described above, the first protrusions 38a and the second protrusions 38b are provided on the side wall 36b of each fin 36. The first protrusion 38a is a protrusion that directs the flow of the cooling fluid toward the bottom portion 36c of the fin 36.

As illustrated in FIG. 8, the cooling fluid flowing in the flow path 34 flows along the flow path 34 as indicated by arrows F until reaching the first protrusion 38a. In the flow of the arrows F, as illustrated in FIG. 9, flow velocity at the center of the flow path is high, and the flow velocity decreases as approaching a flow path wall. This is because a boundary layer 90 (indicated by dots in FIG. 9) due to a viscosity of the cooling fluid is generated in the flow path wall. It is known that the cooling capacity decreases when the boundary layer 90 is formed. Thus, in the present example embodiment, as indicated by arrows G1, G2 in FIG. 8, the first protrusions 38a direct the flow of the cooling fluid in the flow path 34 toward a direction of the bottom portion 36c of the fin 36, so that the boundary layer on the board member 28 side to which the semiconductor element 53 is attached is destroyed (or generation of the boundary layer is reduced), and the decrease in the cooling capacity is suppressed.

When the flow of the cooling fluid is directed to the fin bottom portion 36c (the bottom portion of the flow path 34) by the first protrusion 38a, it is possible that a low flow velocity area 56 is generated in a lower stream with respect to the first protrusion 38a. Since the cooling capacity decreases in the low flow velocity area, the second protrusion 38b directs the flow of the cooling fluid toward the low flow velocity area 56 (arrows J1, J2) to suppress the decrease in the cooling capacity.

Since the protrusions 38 (first protrusions 38a and second protrusions 38b) are elements that maintain the cooling capacity of the cooling device 20 (suppress the decrease in the cooling capacity), as shown in FIG. 3, positions in which the protrusions 38 are formed correspond to the positions of the semiconductor elements 51, 52, and 53. Consequently, according to the cooling device 20 of the present example embodiment, the heating elements (51 to 53) are allowed to be sufficiently cooled.

The cooling device 20 of the present disclosure is not limited to the configuration described above. For example, the following modifications are possible. (1) A heat pipe may be provided between the cooling device 20 and the board member 28. The heat pipe achieves an improvement of heat radiation efficiency of the cooling device 20. (2) The board member 28 may be replaced with a vapor chamber. A housing of the vapor chamber is made of, for example, copper. By using the vapor chamber instead of the board member 28, the improvement of the heat radiation efficiency of the cooling device 20 is achieved.

(3) The cooling device 20 may not be composed of the plurality of U-shaped fins 36. For example, the cooling device 20 may be composed of a first plate member, a plurality of heat radiation fins provided vertically from the first plate member toward a second plate member, and the second plate member provided to cover the plurality of heat radiation fins. Also in the above case, the flow path is formed between the first plate member and the second plate member, and a height of each heat radiation fin at the outlet of the flow path is reduced from the second plate member side toward the first plate member side. In this cooling device, a shape of the fin is not the U-shape but an I-shape. Alternatively, the flow path (cooling device) may be formed by connecting a plurality of L-shaped fins and providing a plate member thereon, and a height of each fin may be reduced at the outlet of the flow path.

(4) The height H2 of the low back portion 36d may not be constant. For example, the low back portion 36d may be inclined. In the case of being inclined, for example, the height H2 of the low back portion 36d decreases as approaching the flow path outlet 34b.

(5) Each of the semiconductor elements 51 to 53 is an example of the heating element, and the cooling device 20 of the present disclosure may also be applied to an “object that generates heat” other than the semiconductor element.

(6) Although the three semiconductor elements 51 to 53 are attached to the cooling device 20, the number of semiconductor elements may be one or more.

(7) Although the semiconductor elements 51, 52, and 53 are the insulated gate bipolar transistors, one or two of the three semiconductor elements may not be the insulated gate bipolar transistors. For example, the insulated gate bipolar transistor may be replaced with a field effect transistor or the like. Alternatively, all of the three semiconductor elements 51 to 53 may be the field effect transistors or the like.

(8) In FIGS. 3A to 3B, with regard to the semiconductor element 51 closest to the flow path inlet, although only a part of the semiconductor element 51 is located under the cooling device 20, the whole of the semiconductor element 51 may be located under the cooling device 20. That is, the portion where the side wall portion 36b of each fin 36 is in contact with the lower surface portion 36c may be superimposed on the entire semiconductor element 51. In the above case, although the length of each fin 36 is extended in the −X direction, the height of the fin 36 is set to H2 in an extended portion. That is, in the flow path inlet 34a, each fin may have the low back portion as the extended portion. The above configuration will be described later as a second example embodiment.

In the case that the height of the side wall portion 36b of each fin 36 is reduced also at the inlet 34a of the flow path 34, when the cooling fluid flows in the flow path 34, the cooling fluid flowing through the first connection portion 25 in the vertical direction (lower direction) makes it possible to gradually change its own angle toward the horizontal direction, and thus easily flows into the flow path 34. Since the lower portion (lower surface portion 36c of the fin 36) of the flow path 34 is not cut off, a bottom wall of the cooling device 20 makes it possible to cover the semiconductor element 51 at the flow path inlet 34a, and to sufficiently cool the semiconductor element 51.

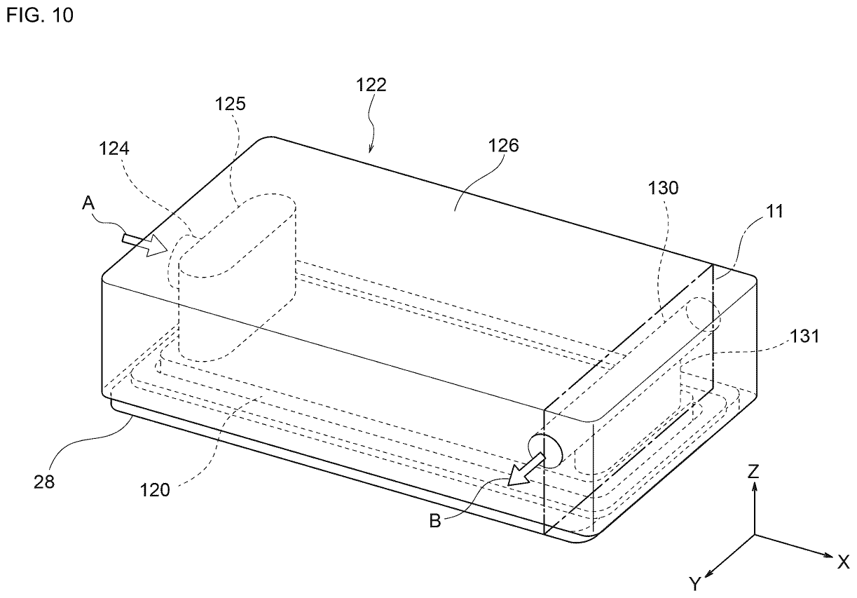

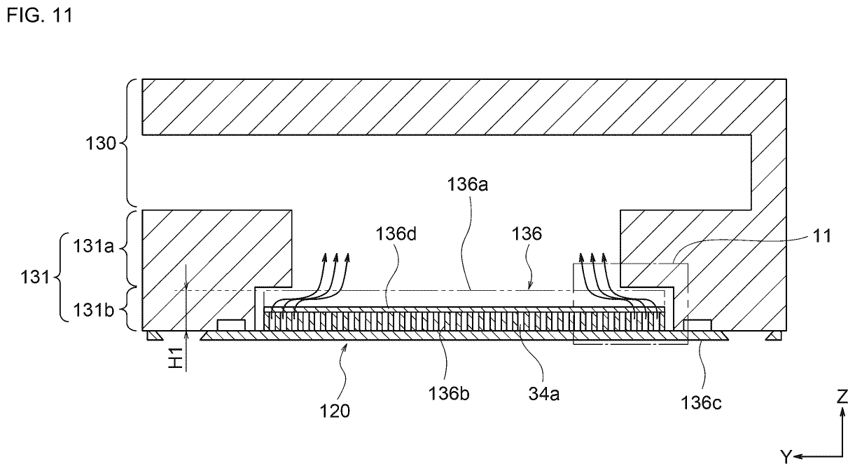

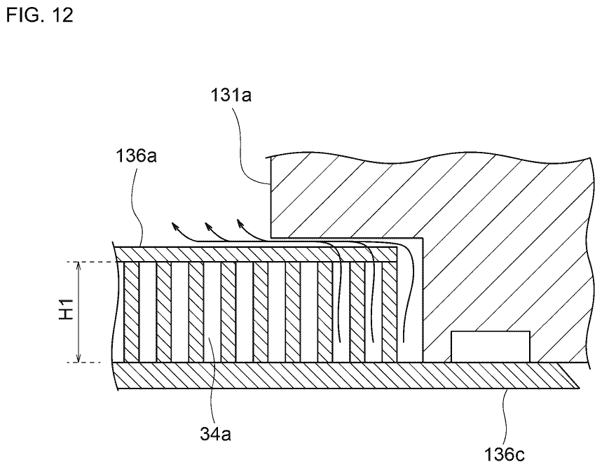

A cooling device 120 according to a second example embodiment of the present disclosure will be described with reference to FIGS. 10 to 12 hereinafter. FIG. 10 is a perspective view of a cooling system 122 including the cooling device 120. FIG. 10 is drawn in perspective. FIG. 11 is a cross sectional view of a portion denoted by reference numeral 11 in FIG. 10, and illustrates details of the vicinity of the flow path outlet of the cooling device 120 when viewed from the −X direction. FIG. 12 is a view illustrating a fourth comparative example, and is an enlarged cross sectional view of a configuration corresponding to a portion denoted by reference numeral 12 in FIG. 11.

In the following description, configurations similar to those in the first example embodiment are denoted by the same reference numerals as those in the first example embodiment. The cooling system 122 according to the second example embodiment differs from the cooling system 22 according to the first example embodiment in shapes of an introduction pipe portion 124, a first connection portion 125, a cover member 126, an outflow pipe portion 130, and a second connection portion 131. Arrangement of the semiconductor elements 51 to 53 with respect to the board member 28 is the same as that in the first example embodiment.

A main difference between the cooling device 20 of the first example embodiment and the cooling device 120 of the second example embodiment is that each fin 136b has a low back portion also at a flow path inlet. Although the flow of the cooling fluid in the cooling device 120 is substantially the same as that in the first example embodiment, since each fin 136b has the low back portion at the flow path inlet, the cooling fluid flowing in the flow path inlet from the first connection portion 125 makes it possible to smoothly flow into the flow path from the low back portion of the fin 136b. Each fin 136b is extended in the −X direction as compared with the first example embodiment, and the fin 136b covers the whole of the semiconductor element 51 in top view. The differences from the cooling device 20 of the first example embodiment will be mainly described hereinafter.

The cooling device 120 includes a bottom member 136c, a plurality of the side wall portions (fins) 136b extending in the Z direction from the bottom member 136c, and an upper surface member 136a provided on the plurality of fins 136b. In FIG. 11, an upper side of the upper surface member 136a is indicated by a two-dot chain line for convenience of illustration. As in the first example embodiment, the cooling device 120 has the low back portion 136d at the flow path outlet 34b. The inter-fin passage 34c is formed between the fins 136b adjacent to each other. The board member 28 is located under the bottom member 136c.

In the present example embodiment, the second connection portion 131 covers the entire vicinity of an outlet of the cooling device 120. The second connection portion 131 has an upper portion 131a and a lower portion 131b. The upper portion 131a of the second connection portion 131 overhangs the upper surface member 136a of the cooling device 120. The upper portion 131a of the second connection portion 131 is connected to the outflow pipe portion 130. It is to be noted that the second connection portion 131 is integrated with the cover member 126.

Since the cooling device 120 has the low back portion 136d at the flow path outlet, as in the first example embodiment, the height of each fin 136 is H1 from the flow path inlet 34a to the front of the inflow outlet 34b, and the height is H2 at the flow path outlet 34b. The cooling device 120 has the low back portion 136d also at the flow path inlet.

In the present example embodiment, since the upper portion 131a of the second connection portion 131 protrudes more inward in a flow path width direction than the lower portion 131b and extends to the upper portion of the cooling device 120, when the cooling fluid flows from the flow path outlet 34b to the upper portion 131a of the second connection portion 131, it is possible that the upper portion 131a of the second connection portion 131 becomes an obstacle to the cooling fluid on both sides in the flow path width direction. That is, as illustrated in FIG. 12, in the case that the cooling device 120 (or the fin 136) does not have the low back portion 136d, a gap between the upper portion 131a of the second connection portion 131 and the upper surface member 136a of the cooling device 120 becomes small, and the flow of the cooling fluid is inhibited.

On the other hand, in the present example embodiment, as illustrated in FIG. 11, since each fin 136 has the low back portion 136d, a sufficient space through which the cooling fluid flows is secured between the upper surface member 136a of the cooling device 120 and the upper portion 131a of the second connection portion 131.

It is to be noted that the second example embodiment is not limited to the above-described configuration. The configurations (1) to (7) described as the modifications of the first example embodiment may be appropriately adopted for example.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

1-19. (canceled)

20: A cooling device comprising:
a first surface portion thermally connected to one or more heating elements provided along a direction in which a cooling fluid flows;
a second surface portion opposed to the first surface portion;
a flow path between the first surface portion and the second surface portion, through which the cooling fluid flows; and
a side wall connecting the first surface portion and the second surface portion and extending along the direction in which the cooling fluid flows; wherein
a height of the side wall is reduced from the second surface portion side toward the first surface portion side at an outlet of the flow path;
at least a portion of the second surface portion is missing in a portion of the side wall of which the height is reduced; and
a portion where the side wall is in contact with the first surface portion is superimposed on at least an entirety of one of the one or more heating elements closest to the outlet of the flow path.

21: The cooling device according to claim 20, wherein the height of the side wall is reduced from the second surface portion side toward the first surface portion side also at an inlet of the flow path.

22: The cooling device according to claim 20, further comprising a first protrusion that is provided on the side wall to direct a flow of the cooling fluid toward the first surface portion.

23: The cooling device according to claim 22, further comprising a second protrusion that is provided on the side wall in a lower stream with respect to the first protrusion to direct the flow of the cooling fluid toward a low flow velocity area generated by the first protrusion.

24: The cooling device according to claim 23, wherein each of positions where the first protrusion and the second protrusion are located corresponds to a position of each of the one or more heating elements.

25: The cooling device according to claim 23, wherein the first protrusion is inclined at a first predetermined angle with respect to the direction in which the cooling fluid flows in the flow path, and the second protrusion is inclined at an angle different from the first predetermined angle with respect to a longitudinal direction of the flow path.

26: The cooling device according to claim 23, wherein each of the first protrusion and the second protrusion is inclined at or substantially at 30 degrees with respect to a longitudinal direction of the flow path.

27: The cooling device according to claim 20, wherein the height of the portion of the side wall where the height is reduced is about ½ or less of the height of a portion of which the height is not reduced.

28: The cooling device according to claim 20, wherein the height of the portion of the side wall where the height is reduced is not constant.

29: The cooling device according to claim 20, wherein the first protrusion and the second protrusion are in contact with a side wall opposed to the side wall.

30: The cooling device according to claim 20, wherein the first protrusion and the second protrusion are defined by a punched out structure.

31: The cooling device according to claim 20, wherein the one or more heating elements are provided on the first surface portion via a plate-shaped portion including a copper plate.

32: The cooling device according to claim 31, wherein the plate-shaped portion is a vapor chamber including a copper housing.

33: The cooling device according to claim 20, wherein the one or more heating elements are provided on the first surface portion via a heat pipe.

34: The cooling device according to claim 20, wherein at least one of the one or more heating elements is an insulated gate bipolar transistor.

35: The cooling device according to claim 20, wherein the first surface portion, the side wall, and the second surface portion are defined by one metal plate having a U-shape, and the flow path is defined by connecting a plurality of the metal plates each having the U-shape in a direction parallel to the first surface portion and perpendicular to the direction in which the cooling fluid flows.

36: The cooling device according to claim 35, wherein the metal plate having the U-shape is a fin portion, and the flow path is defined by a plurality of the fin portions.

37: The cooling device according to claim 35, wherein the metal plate is a copper plate.

38: The cooling device according to claim 20, wherein the side wall includes a plurality of heat dissipation fins provided vertically from the first surface portion toward the second surface portion.
